(19) United States
(12) Patent Application Publication
(10) Pub. No.: US 2015/0275364 A1
(43) Pub. Date: Oct. 1, 2015

(54) Cyclic Spike Anneal Chemical Exposure For Low Thermal Budget Processing

(71) Applicant: Applied Materials, Inc., Santa Clara, CA (US)

(72) Inventors: David Thompson, San Jose, CA (US); Huixiong Dai, San Jose, CA (US); Patrick M. Martin, Ipswich, MA (US); Timothy Michaelson, Milpitas, CA (US); Kadthala R. Narendrnath, San Jose, CA (US); Robert Jan Visser, Menlo Park, CA (US); Jingjing Xu, Cupertino, CA (US); Lin Zhang, San Jose, CA (US)

(21) Appl. No.: 14/666,689

(22) Filed: Mar. 24, 2015

Related U.S. Application Data
(60) Provisional application No. 61/971,256, filed on Mar. 27, 2014.

(51) Int. Cl. C23C 16/455; C23C 16/50; C23C 16/458

(52) U.S. Cl. CPC C23C 16/45544; C23C 16/4584; C23C 16/50

(57) ABSTRACT

Provided are apparatus and methods for the sequential deposition and annealing of a film within a single processing chamber. An energy source positioned within the processing chamber in an area isolated from process gases can be used to rapidly form and decompose a film on the substrate without damaging underlying layers due to exceeding the thermal budget of the device being formed.

### CROSS-REFERENCE TO RELATED APPLICATIONS

This application claims priority to U.S. Provisional Application No. 61/971,256, filed Mar. 27, 2014, the entire disclosure of which is hereby incorporated by reference herein.

### FIELD

Embodiments of the disclosure generally relate to an apparatus for processing substrates. More particularly, embodiments of the disclosure relate to modular capacitively coupled plasma sources for use with processing chambers including batch processors.

### BACKGROUND

Semiconductor device formation is commonly conducted in substrate processing systems or platforms containing multiple chambers, which may also be referred to as cluster tools. In some instances, the purpose of a multi-chamber processing platform or cluster tool is to perform two or more processes on a substrate sequentially in a controlled environment. In other instances, however, a multiple chamber processing platform may only perform a single processing part on substrates. The additional chambers can be employed to maximize the rate at which substrates are processed. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

The effectiveness of a substrate processing platform is often quantified by cost of ownership. The cost of ownership, while influenced by many factors, is largely affected by the system footprint, i.e., the total floor space to operate the system in a fabrication plant, and system throughput, i.e., the number of substrates processed per hour. The footprint typically includes access areas adjacent the system that are used for maintenance. Although a substrate processing platform may be relatively small access from all sides for operation and maintenance may make the effective footprint prohibitively large.

During semiconductor manufacturing, certain processes use high temperatures to ensure that various chemical and physical reactions are completed. One such example of a high temperature process is the epitaxial growth of silicon. When there are underlying layers in a gate stack that are not tolerant of high temperatures, carrying out high temperature reactions may damage or destroy the underlying layers. Front-end-of-line (FEOL) processes allow for high temperature processes but by the time a product reaches the back-end-of-line (BEOL), there are often many layers which cannot tolerate high temperature processes, limiting what processes can be carried out.

Therefore, there is an ongoing need in the art for apparatus and methods for processing high temperature reactions on substrates with low thermal budget.

### SUMMARY

Embodiments of the disclosure are directed to a processing chamber comprising a generally circular gas distribution assembly, a generally circular susceptor assembly and at least one energy source. The general circular gas distribution assembly comprises a plurality of elongate gas ports in a front face of the gas distribution assembly. The plurality of elongate gas ports extend from an inner diameter region to an outer diameter region of the gas distribution assembly. The plurality of gas ports comprises at least one first reactive gas port to deliver a first reactive gas to the processing chamber, a purge gas port to deliver a purge gas to the processing chamber and a vacuum port to evacuate gases from the processing chamber, the vacuum port positioned between the first reactive gas port and the purge gas port. The generally circular susceptor assembly can rotate at least one substrate in a substantially circular path about a rotational axis. The susceptor assembly is positioned below the gas distribution assembly so that a top surface of the susceptor assembly is substantially parallel to the front face of the gas distribution assembly. The susceptor assembly has an inner diameter region and an outer diameter region. The at least one energy source is oriented to direct annealing energy toward the top surface of the susceptor assembly.

Additional embodiments of the disclosure are directed to processing chambers comprising a generally circular gas distribution assembly, a generally circular susceptor assembly and at least one energy source. The generally circular gas distribution assembly comprises a plurality of elongate gas ports in a front face of the gas distribution assembly. The plurality of elongate gas ports extend from an inner diameter region to an outer diameter region of the gas distribution assembly. The plurality of gas ports comprises, in order, a first reactive gas port to deliver a first reactive gas to the processing chamber, a first vacuum port to evacuate gases from the processing chamber, a purge gas port to deliver a purge gas to the processing chamber and a second vacuum port to evacuate gases from the processing chamber. The generally circular susceptor assembly can rotate at least one substrate in a substantially circular path about a rotational axis. The susceptor assembly is positioned below the gas distribution assembly so that a top surface of the susceptor assembly is substantially parallel to the front face of the gas distribution assembly. The susceptor assembly has an inner diameter region and an outer diameter region. The at least one energy source is positioned between the first vacuum port and the second vacuum port and oriented to direct annealing energy toward the top surface of the susceptor assembly. The annealing energy is movable in a direction from the inner diameter region to the outer diameter region of the susceptor assembly.

Further embodiments of the disclosure are directed to processing methods. A substrate is positioned on a rotatable susceptor assembly in a processing chamber. The substrate is laterally moved around a central axis to move the substrate beneath a first reactive gas port of a gas distribution assembly. The first reactive gas port provides a first reactive gas to the processing chamber. The substrate is exposed to a first process condition comprising the first reactive gas to form a partial film on the substrate surface. The substrate is laterally moved around the central axis through at least one vacuum region defining a boundary of the first process condition. The gas distribution assembly has in the vacuum region a vacuum port to evacuate gases from the processing chamber. The substrate surface is exposed to annealing energy to convert the partial film to a film.

### BRIEF DESCRIPTION OF THE DRAWINGS

So that the manner in which the above recited features of the present invention can be understood in detail, a more particular description of the disclosure, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a cross-sectional side view of a spatial atomic layer deposition chamber in accordance with one or more embodiment of the disclosure;

FIG. 2 shows a perspective view of a susceptor in accordance with one or more embodiments of the disclosure;

FIG. 3 shows a schematic of a pie-shaped gas distribution assembly in accordance with one or more embodiments of the disclosure;

FIG. 4 is a schematic plan view of a substrate processing system configured with four gas distribution assembly units with a loading station in accordance with one or more embodiments of the disclosure;

FIG. 5 is a schematic plan view of a substrate processing system configured with three gas distribution assembly units;

FIG. 6 shows a cross-sectional view of a processing chamber in accordance with one or more embodiments of the disclosure;

FIG. 7 shows a perspective view of a susceptor assembly and gas distribution assembly units in accordance with one or more embodiments of the disclosure;

FIG. 8 shows a cross-sectional view of a processing chamber in accordance with one or more embodiments of the disclosure;

FIG. 9 shows a schematic of a pie-shaped gas distribution assembly in accordance with one or more embodiments of the disclosure;

FIG. 10 shows a schematic of a portion of a pie-shaped gas distribution assembly in accordance with one or more embodiment of the disclosure;

FIG. 11A shows a schematic cross-sectional view of a gas distribution assembly with energy source in accordance with one or more embodiment of the disclosure; and

FIG. 11B shows a schematic cross-sectional view of a gas distribution assembly with energy source in accordance with one or more embodiment of the disclosure.

### DETAILED DESCRIPTION

Embodiments of the disclosure provide a substrate processing system for continuous substrate deposition to maximize throughput and improve processing efficiency and uniformity. The substrate processing system can also be used for pre-deposition and post-deposition substrate treatments. Embodiments of the disclosure are related to apparatus and methods for increasing deposition uniformity in a batch processor.

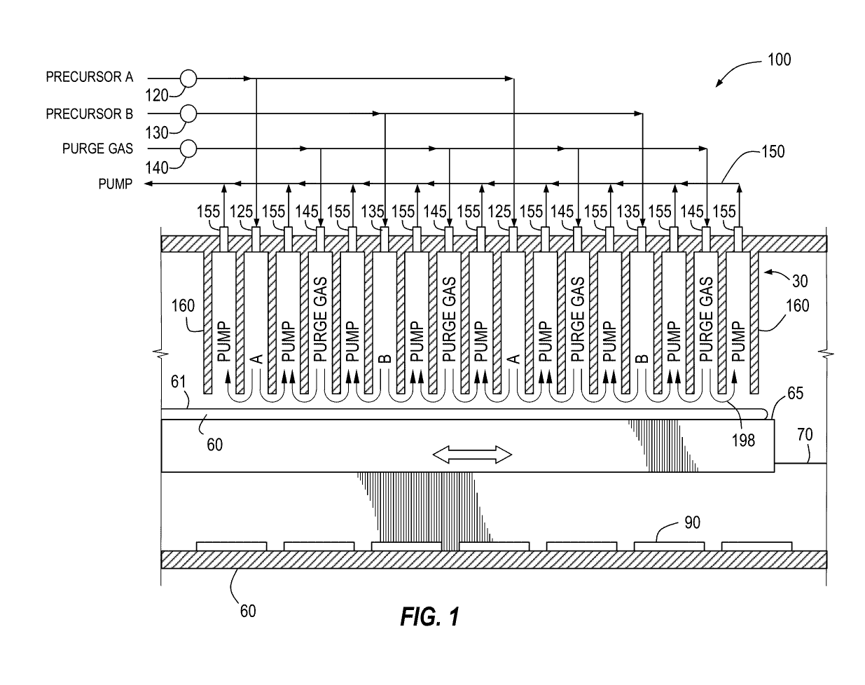

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited or formed thereon.

As used in this specification and the appended claims, the terms “reactive gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

Aspects of the disclosure pertain to utilization of short time laser spike anneal with deposition processes. The lasers rapidly scan over a wafer and make the wafer very hot for a very short amount of time. Such lasers are not typically done during deposition processes because the laser would interfere with the deposition gases and the gases would interfere with the laser optics.

In one or more embodiments, laser spike anneal is combined with spatial atomic layer deposition processes. Deposition of a film may be carried out in a chemical area, the wafer moved to a laser area where the film gets hardened, and then back to the chemical area for additional deposition. For example, silane adsorbs onto a wafer surface at 300° C. but is not set until 10,000° C. With the laser spike anneal process, the silane can be deposited at a lower temperature, and then briefly exposed to the high temperatures of the laser without damaging the underlying layers. In some embodiments, the spike anneal may be done in a temporally where the gases are evacuated from the chamber before lasing the surface or by moving the wafer to a separate processing chamber for lasing.

FIG. 1 is a schematic cross-sectional view of a portion of a processing chamber 20 in accordance with one or more embodiments of the disclosure. The processing chamber 20 is generally a sealable enclosure, which is operated under vacuum, or at least low pressure conditions. The system 100 includes a gas distribution assembly 30 capable of distributing one or more gases across the top surface 61 of a substrate 60. The gas distribution assembly 30 can be any suitable assembly known to those skilled in the art, and specific gas distribution assemblies described should not be taken as limiting the scope of the invention. The output face of the gas distribution assembly 30 faces the first surface 61 of the substrate 60.

Substrates for use with the embodiments of the disclosure can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution assembly 30 comprises a plurality of gas ports to transmit one or more gas streams to the substrate 60 and a plurality of vacuum ports disposed between each gas port to transmit the gas streams out of the processing chamber 20. In the embodiment of FIG. 1, the gas distribution assembly 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 20 through a plurality of gas ports 125. The precursor injector 130 injects a continuous (or pulse) stream of a reactive precursor of compound B into the processing chamber 20 through a plurality of gas ports 135. The purge gas injector 140 injects a continuous (or pulse) stream of a non-reactive or purge gas into the processing chamber 20 through a plurality of gas ports 145. The purge gas removes reactive material and reactive by-products from the processing chamber 20. The purge gas is typically an inert gas, such as, nitrogen, argon and helium. Gas ports 145 are disposed in between gas ports 125 and gas ports 135 so as to separate the precursor of compound A from the precursor of compound B, avoiding cross-contamination between the precursors.

In another aspect, a remote plasma source (not shown) may be connected to the precursor injector 120 and the precursor injector 130 prior to injecting the precursors into the processing chamber 20. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, the power source can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system 100 further includes a pumping system 150 connected to the processing chamber 20. The pumping system 150 is generally configured to evacuate the gas streams out of the processing chamber 20 through one or more vacuum ports 155. The vacuum ports 155 are disposed between each gas port so as to evacuate the gas streams out of the processing chamber 20 after the gas streams react with the substrate surface and to further limit cross-contamination between the precursors.

The system 100 includes a plurality of partitions 160 disposed on the processing chamber 20 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the invention. It will be understood by those skilled in the art that the gas distribution system shown is merely one possible distribution system and the other types of showerheads and gas distribution assemblies may be employed.

Atomic layer deposition systems of this sort (i.e., where multiple gases are separately flowed toward the substrate at the same time) are referred to as spatial ALD. In operation, a substrate 60 is delivered (e.g., by a robot) to the processing chamber 20 and can be placed on a shuttle 65 before or after entry into the processing chamber. The shuttle 65 is moved along the track 70, or some other suitable movement mechanism, through the processing chamber 20, passing beneath (or above) the gas distribution assembly 30. In the embodiment shown in FIG. 1, the shuttle 65 is moved in a linear path through the chamber. FIG. 3, as explained further below, shows an embodiment in which wafers are moved in a circular path through a carousel processing system.

Referring back to FIG. 1, as the substrate 60 moves through the processing chamber 20, the first surface 61 of substrate 60 is repeatedly exposed to the reactive gas A coming from gas ports 125 and reactive gas B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the reactive gases or the purge gas), the gas streams are evacuated through the vacuum ports 155 by the pumping system 150. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps and can occur while the substrate is passing beneath the gas distribution assembly 30 or when the substrate is in a region before and/or after the gas distribution assembly 30.

Sufficient space is generally provided after the gas distribution assembly 30 to ensure complete exposure to the last gas port. Once the substrate 60 has completely passed beneath the gas distribution assembly 30, the first surface 61 has completely been exposed to every gas port in the processing chamber 20. The substrate can then be transported back in the opposite direction or forward. If the substrate 60 moves in the opposite direction, the substrate surface may be exposed again to the reactive gas A, the purge gas, and reactive gas B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 61. The width between each partition, the number of gas ports disposed on the processing chamber 20, and the number of times the substrate is passed across the gas distribution assembly may also determine the extent to which the substrate surface 61 is exposed to the various gases. Consequently, the quantity and quality of a deposited film may be optimized by varying the above-referenced factors.

Although description of the process has been made with the gas distribution assembly 30 directing a flow of gas downward toward a substrate positioned below the gas distribution assembly, the orientation can be different. In some embodiments, the gas distribution assembly 30 directs a flow of gas upward toward a substrate surface. As used in this specification and the appended claims, the term “passed across” means that the substrate has been moved from one side of the gas distribution assembly to the other side so that the entire surface of the substrate is exposed to each gas stream from the gas distribution plate. Absent additional description, the term “passed across” does not imply any particular orientation of gas distribution assemblies, gas flows or substrate positions.

In some embodiments, the shuttle 65 is a susceptor 66 for carrying the substrate 60. Generally, the susceptor 66 is a carrier which helps to form a uniform temperature across the substrate. The susceptor 66 is movable in both directions (left-to-right and right-to-left, relative to the arrangement of FIG. 1) or in a circular direction (relative to FIG. 3). The susceptor 66 has a top surface 67 for carrying the substrate 60. The susceptor 66 may be a heated susceptor so that the substrate 60 may be heated for processing. As an example, the susceptor 66 may be heated by radiant heat lamps 90, a heating plate, resistive coils, or other heating devices, disposed underneath the susceptor 66.

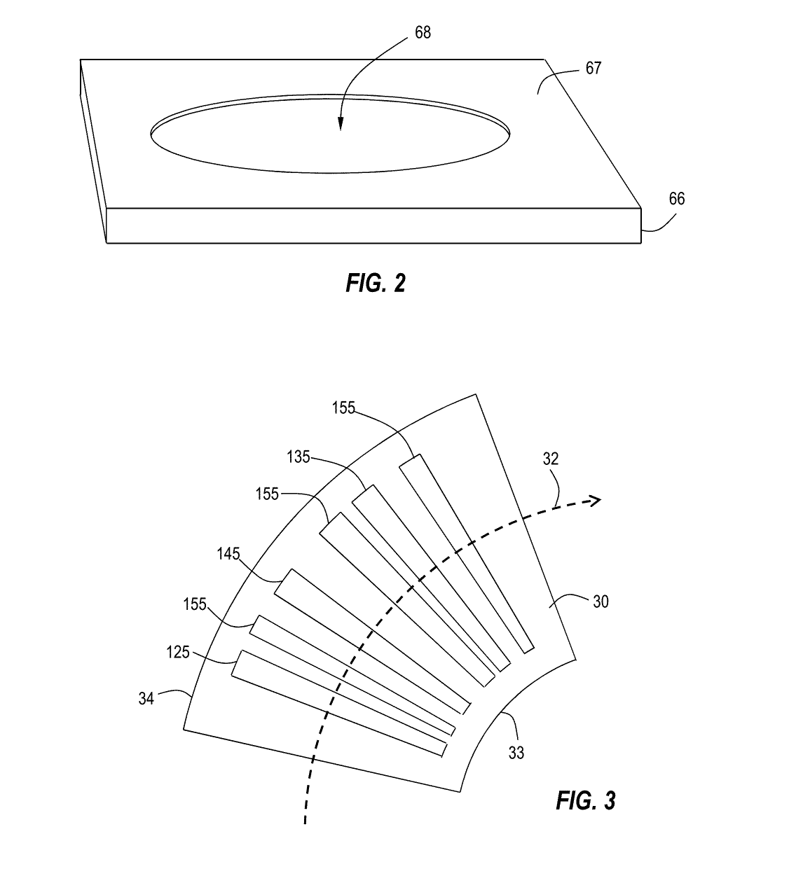

In still another embodiment, the top surface 67 of the susceptor 66 includes a recess 68 to accept the substrate 60, as shown in FIG. 2. The susceptor 66 is generally thicker than the thickness of the substrate so that there is susceptor material beneath the substrate. In some embodiments, the recess 68 is sized such that when the substrate 60 is disposed inside the recess 68, the first surface 61 of substrate 60 is level with, or substantially coplanar with, the top surface 67 of the susceptor 66. Stated differently, the recess 68 of some embodiments is sized such that when a substrate 60 is disposed therein, the first surface 61 of the substrate 60 does not protrude above the top surface 67 of the susceptor 66. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

FIG. 1 shows a cross-sectional view of a processing chamber in which the individual gas ports are shown. This embodiment can be either a linear processing system in which the width of the individual gas ports is substantially the same across the entire width of the gas distribution plate, or a pie-shaped segment in which the individual gas ports change width to conform to the pie shape. FIG. 3 shows a portion of a pie-shaped gas distribution assembly 30. A substrate would be passed across this gas distribution assembly 30 in an arc shape path 32. Each of the individual gas ports 125, 135, 145, 155 have a narrower width near the inner peripheral edge 33 of the gas distribution assembly 30 a and a larger width near the outer peripheral edge 34 of the gas distribution assembly 30. The shape or aspect ratio of the individual ports can be proportional to, or different from, the shape or aspect ratio of the gas distribution assembly 30 segment. In some embodiments, the individual ports are shaped so that each point of a wafer passing across the gas distribution assembly 30 following path 32 would have about the same residence time under each gas port. The path of the substrates can be perpendicular to the gas ports. In some embodiments, each of the gas distribution assemblies comprise a plurality of elongate gas ports which extend in a direction substantially perpendicular to the path traversed by a substrate. As used in this specification and the appended claims, the term “substantially perpendicular” means that the general direction of movement is approximately perpendicular to the axis of the gas ports. For a pie-shaped gas port, the axis of the gas port can be considered to be a line defined as the mid-point of the width of the port extending along the length of the port. As described further below, each of the individual pie-shaped segments can be configured to deliver a single reactive gas or multiple reactive gases separated spatially or in combination (e.g., as in a typical CVD process).

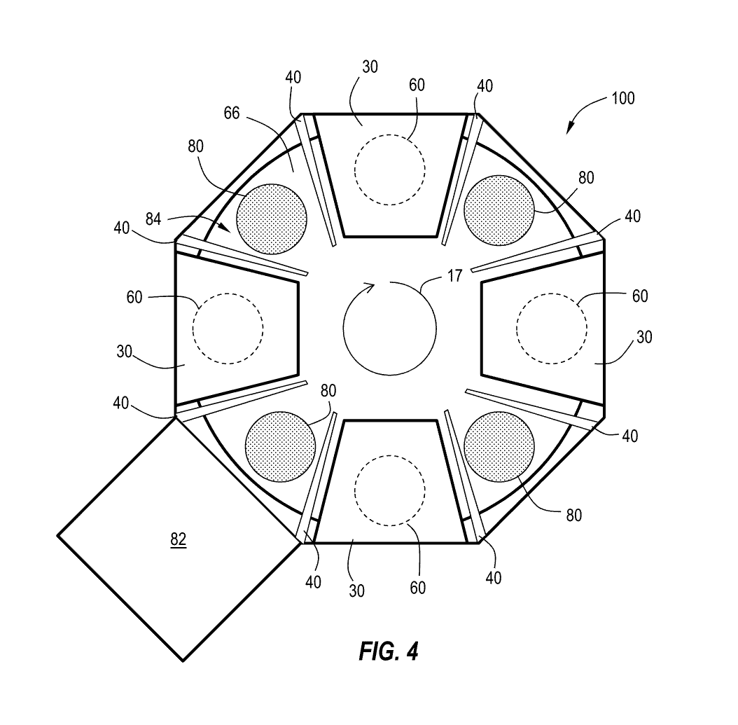

Processing chambers having multiple gas injectors can be used to process multiple wafers simultaneously so that the wafers experience the same process flow. For example, as shown in FIG. 4, the processing chamber 100 has four gas injector assemblies 30 and four wafers 60. At the outset of processing, the wafers 60 can be positioned between the injector assemblies 30. Rotating the susceptor 66 of the carousel by 45° will result in each wafer 60 being moved to an injector assembly 30 for film deposition. This is the position shown in FIG. 4. An additional 45° rotation would move the wafers 60 away from the injector assemblies 30. With spatial ALD injectors, a film is deposited on the wafer during movement of the wafer relative to the injector assembly. In some embodiments, the susceptor 66 is rotated so that the wafers 60 do not stop beneath the injector assemblies 30. The number of wafers 60 and gas distribution assemblies 30 can be the same or different. In some embodiments, there are the same number of wafers being processed as there are gas distribution assemblies. In one or more embodiments, the number of wafers being processed are an integer multiple of the number of gas distribution assemblies. For example, if there are four gas distribution assemblies, there are 4x wafers being processed, where x is an integer value greater than or equal to one.

The processing chamber 100 shown in FIG. 4 is merely representative of one possible configuration and should not be taken as limiting the scope of the invention. Here, the processing chamber 100 includes a plurality of gas distribution assemblies 30. In the embodiment shown, there are four gas distribution assemblies 30 evenly spaced about the processing chamber 100. The processing chamber 100 shown is octagonal, however, those skilled in the art will understand that this is one possible shape and should not be taken as limiting the scope of the invention. The gas distribution assemblies 30 shown are rectangular, but those skilled in the art will understand that the gas distribution assemblies can be pie-shaped segments, like that shown in FIG. 3. Additionally, each segment can be configured to deliver gases in a spatial type arrangement with multiple different reactive gases flowing from the same segment or configured to deliver a single reactive gas or a mixture of reactive gases.

The processing chamber 100 includes a substrate support apparatus, shown as a round susceptor 66 or susceptor assembly. The substrate support apparatus, or susceptor 66, is capable of moving a plurality of substrates 60 beneath each of the gas distribution assemblies 30. A load lock 82 might be connected to a side of the processing chamber 100 to allow the substrates 60 to be loaded/unloaded from the chamber 100.

The processing chamber 100 may include a plurality, or set, of first treatment stations 80 positioned between any or each of the plurality of gas distribution assemblies 30. In some embodiments, each of the first treatment stations 80 provides the same treatment to a substrate 60.

The number of treatment stations and the number of different types of treatment stations can vary depending on the process. For example, there can be one, two, three, four, five, six, seven or more treatment stations positioned between the gas distribution assemblies 30. Each treatment stations can independently provide a different treatment from every other set of treatments station, or there can be a mixture of the same type and different types of treatments. In some embodiments, one or more of the individual treatments stations provides a different treatment than one or more of the other individual treatment stations. The embodiment shown in FIG. 4 shows four gas distribution assemblies with spaces between which can include some type of treatment station. However, it can be easily envisioned from this drawing that the processing chamber can readily be incorporated with eight gas distribution assemblies with the gas curtains between.

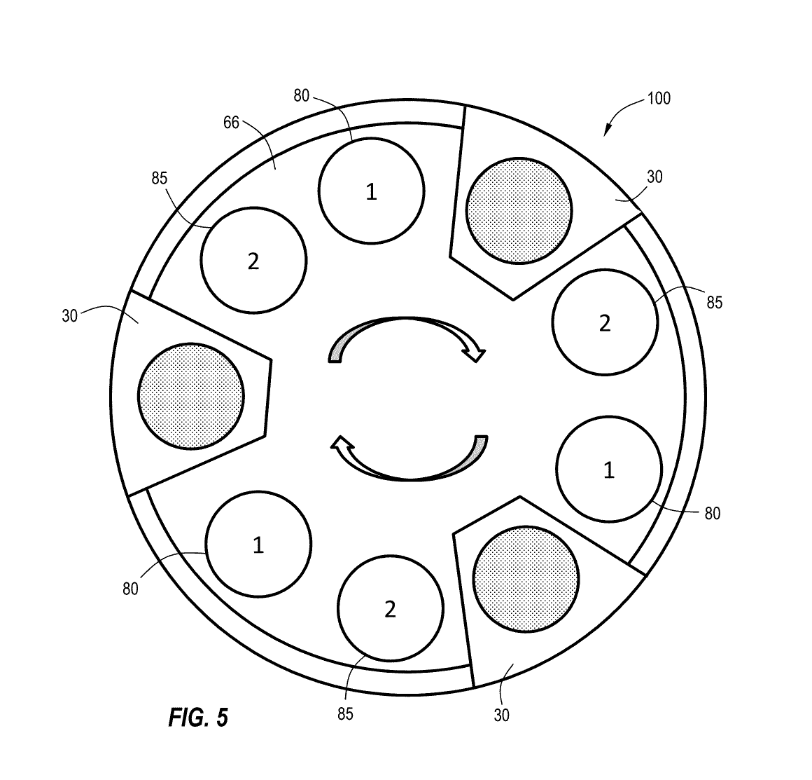

In the embodiment shown in FIG. 5, a set of second treatment stations 85 are positioned between the first treatment stations 80 and the gas distribution assemblies 30 so that a substrate 60 rotated through the processing chamber 100 would encounter, depending on where the substrate 60 starts, a gas distribution assembly 30, a first treatment station 80 and a second treatment station 85 before encountering a second of any of these. For example, as shown in FIG. 5, if the substrate started at the first treatment station 80, the substrate surface would “see” or be exposed to, in order, the first treatment station 80, a gas distribution assembly 30 and a second treatment station 85 before encountering a second first treatment station 85.

Treatment stations can provide any suitable type of treatment to the substrate, film on the substrate or susceptor assembly. For example, UV lamps, flash lamps, plasma sources and heaters. The wafers are then moved between positions with the gas distribution assemblies 30 to a position with, for example, a showerhead delivering plasma to the wafer. The plasma station being referred to as a treatment station 80. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where rotation can pause again. Pausing between the injectors may provide time for additional processing between each layer deposition (e.g., exposure to plasma).

In some embodiments, the processing chamber comprises a plurality of gas curtains 40. Each gas curtain 40 creates a barrier to prevent, or minimize, the movement of processing gases from the gas distribution assemblies 30 from migrating from the gas distribution assembly regions and gases from the treatment stations 80 from migrating from the treatment station regions. The gas curtain 40 can include any suitable combination of gas and vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain 40 is a combination of vacuum streams and purge gas streams so that there are, in order, a vacuum stream, a purge gas stream and a vacuum stream. The gas curtains 40 shown in FIG. 4 are positioned between each of the gas distribution assemblies 30 and treatment stations 80, but it will be understood that the curtains can be positioned at any point or points along the processing path.

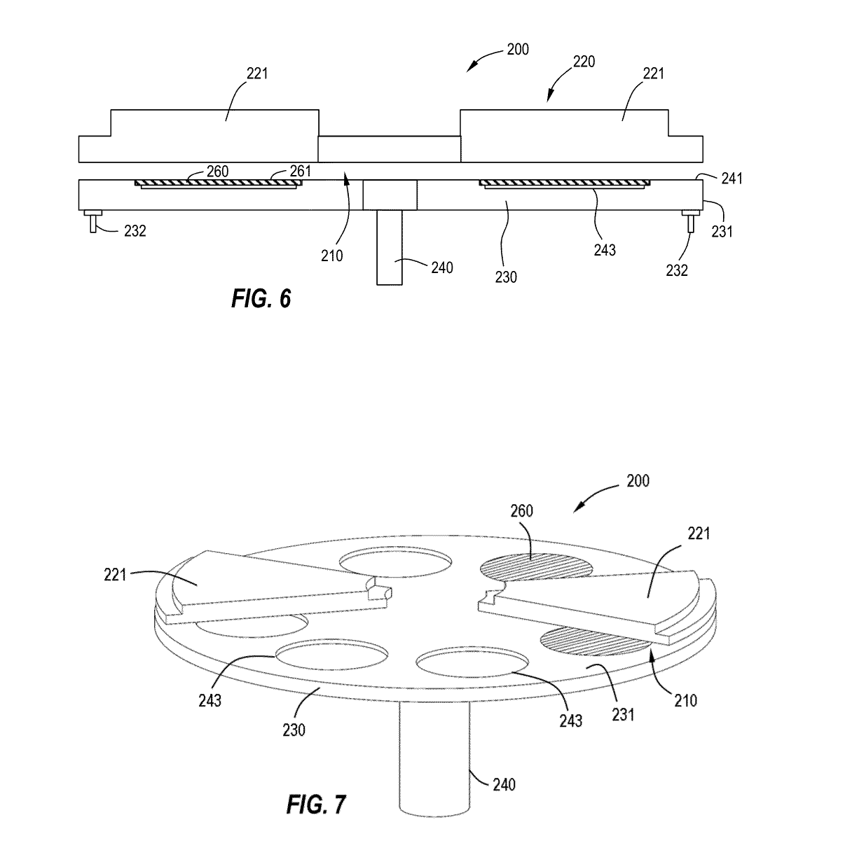

FIG. 6 shows an embodiment of a processing chamber 200 including a gas distribution assembly 220, also referred to as the injectors, and a susceptor assembly 230. In this embodiment, the susceptor assembly 230 is a rigid body. The rigid body of some embodiments has a droop tolerance no larger than 0.05 mm. Actuators 232 are placed, for example, at three locations at the outer diameter region of the susceptor assembly 230. As used in this specification and the appended claims, the terms “outer diameter” and “inner diameter” refer to regions near the outer peripheral edge and the inner edge, respectively. The outer diameter is not to a specific position at the extreme outer edge (e.g., near shaft 240) of the susceptor assembly 230, but is a region near the outer edge 231 of the susceptor assembly 230. This can be seen in FIG. 6 from the placement of the actuators 232. The number of actuators 232 can vary from one to any number that will fit within the physical space available. Some embodiments have two, three, four or five sets of actuators 232 positioned in the outer diameter region 231. As used in this specification and the appended claims, the term “actuator” refers to any single or multi-component mechanism which is capable of moving the susceptor assembly 230, or a portion of the susceptor assembly 230, toward or away from the gas distribution assembly 220. For example, actuators 232 can be used to ensure that the susceptor assembly 230 is substantially parallel to the gas distribution assembly 220. As used in this specification and the appended claims, the term “substantially parallel” used in this regard means that the parallelism of the components does not vary by more than 5% relative to the distance between the components.

Once pressure is applied to the susceptor assembly 230 from the actuators 232, the susceptor assembly 230 can be levelled. As the pressure is applied by the actuators 232, the gap 210 distance can be set to be within the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The susceptor assembly 230 is positioned beneath the gas distribution assembly 220. The susceptor assembly 230 includes a top surface 241 and, optionally, at least one recess 243 in the top surface 241. The recess 243 can be any suitable shape and size depending on the shape and size of the wafers 260 being processed. In the embodiment shown, the recess 241 has a step region around the outer peripheral edge of the recess 241. The steps can be sized to support the outer peripheral edge of the wafer 260. The amount of the outer peripheral edge of the wafer 260 that is supported by the steps can vary depending on, for example, the thickness of the wafer and the presence of features already present on the back side of the wafer.

In some embodiments, as shown in FIG. 6, the recess 243 in the top surface 241 of the susceptor assembly 230 is sized so that a wafer 260 supported in the recess 243 has a top surface 261 substantially coplanar with the top surface 241 of the susceptor assembly 230. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 230 of FIG. 6 includes a support post 240 which is capable of lifting, lowering and rotating the susceptor assembly 230. The susceptor assembly 230 may include a heater, or gas lines, or electrical components within the center of the support post 240. The support post 240 may be the primary means of increasing or decreasing the gap between the susceptor assembly 230 and the gas distribution assembly 220, moving the susceptor assembly 230 into rough position. The actuators 232 can then make micro-adjustments to the position of the susceptor assembly to create the desired gap.

The processing chamber 100 shown in FIG. 6 is a carousel-type chamber in which the susceptor assembly 230 can hold a plurality of wafers 260. The gas distribution assembly 220 may include a plurality of separate injector units 221, each injector unit 221 being capable of depositing a film or part of a film on the wafer 260, as the wafer is moved beneath the injector unit 221. FIG. 7 shows a perspective view of a carousel-type processing chamber 200. Two pie-shaped injector units 221 are shown positioned on approximately opposite sides of and above the susceptor assembly 230. This number of injector units 221 is shown for illustrative purposes only. It will be understood that more or less injector units 221 can be included. In some embodiments, there are a sufficient number of pie-shaped injector units 221 to form a shape conforming to the shape of the susceptor assembly 230. In some embodiments, each of the individual pie-shaped injector units 221 may be independently moved, removed and/or replaced without affecting any of the other injector units 221. For example, one segment may be raised to permit a robot to access the region between the susceptor assembly 230 and gas distribution assembly 220 to load/unload wafers 260.

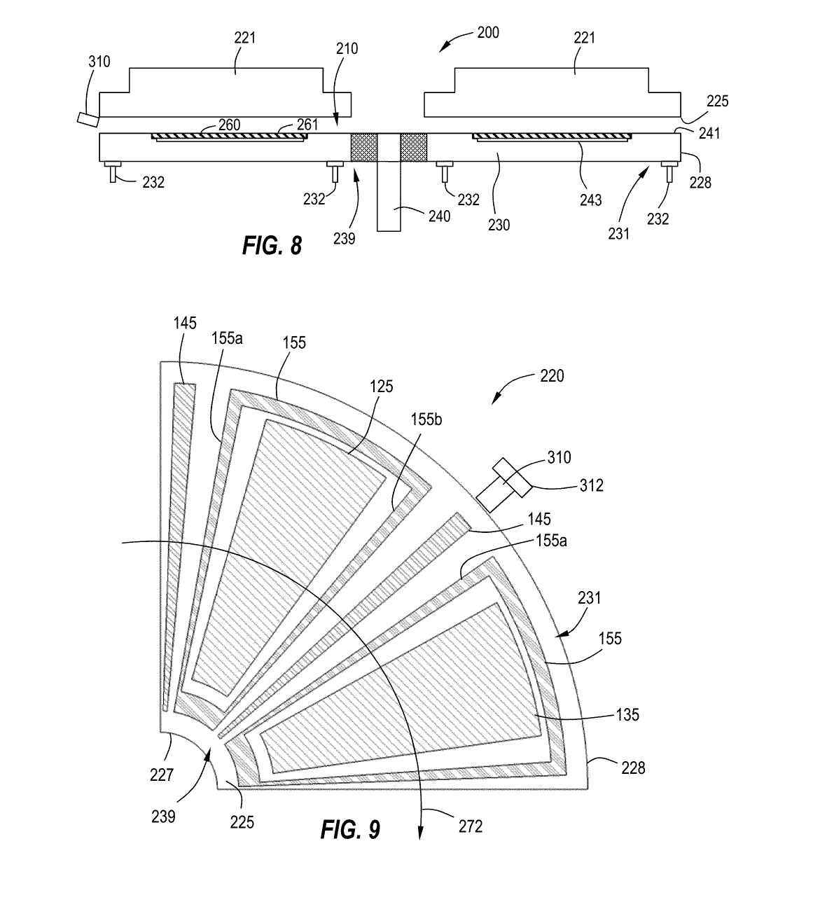

FIG. 8 shows another embodiment of the disclosure in which the susceptor assembly 230 is not a rigid body. In some embodiments, the susceptor assembly 230 has a droop tolerance of not more than about 0.1 mm, or not more than about 0.05 mm, or not more than about 0.025 mm, or not more than about 0.01 mm. Here, there are actuators 232 placed at the outer diameter region 231 and at the inner diameter region 239 of the susceptor assembly 230. The actuators 232 can be positioned at any suitable number of places around the inner and outer periphery of the susceptor assembly 230. In some embodiments, the actuators 232 are placed at three locations at both the outer diameter region 231 and the inner diameter region 239. The actuators 232 at both the outer diameter region 231 and the inner diameter region 239 apply pressure to the susceptor assembly 230.

FIG. 9 shows a gas distribution assembly 220 in accordance with one or more embodiment of the disclosure. The front face 225 of a portion or segment of a generally circular gas distribution assembly 220 is shown. As used in this specification and the appended claims, the term “generally circular” means that the overall shape of the component does not have any angles less than 80°. Thus, generally circular can have any shape including square, pentagonal, hexagonal, heptagonal, octagonal, etc. Generally circular should not be taken as limiting the shape to a circle or perfect polygon, but can also include oval and imperfect polygons. The gas distribution assembly 220 includes a plurality of elongate gas ports 125, 135, 145 in the front face 225. The gas ports extend from the inner diameter region 239 to an outer diameter region 231 of the gas distribution assembly 220.

The plurality of gas ports include a first reactive gas port 125 to deliver a first reactive gas to the processing chamber and a purge gas port 145 to deliver a purge gas to the processing chamber. The embodiment shown in FIG. 9 also includes a second reactive gas port 135 to deliver a second reactive gas to the processing chamber.

A vacuum port 155 separates the first reactive gas port 125 and second reactive gas port 135 from the adjacent purge gas ports 145. Stated differently, the vacuum port is positioned between the first reactive gas port 125 and the purge gas port 145 and between the second reactive gas port 135 and the purge gas port 145. The vacuum ports evacuate gases from the processing chamber. In the embodiment shown in FIG. 9, the vacuum ports 155 extend around all sides of the reactive gas ports so that there is a portion of the vacuum port 155 on the inner peripheral edge 227 and outer peripheral edge 228 of each of the first reactive gas port 125 and second reactive gas port 135.

In use, a substrate is passed adjacent the gas distribution plate 220 along path 272. In transit, the substrate will encounter gas flows, either flowing into the chamber or out of the chamber, in order, a purge gas port 145, a first vacuum port 155a, a first reactive gas port 125, a second vacuum port 155b, a purge gas port 145, a first vacuum port 155a, a second reactive gas port 135 and a second vacuum port 155b. The first vacuum port 155a and second vacuum port 155b are shown connected as a single vacuum port 155.

At least one energy source 310 is oriented to direct annealing energy toward the top surface of the susceptor assembly. As used in this specification and the appended claims, the term “energy source” is used to describe a device capable of providing sufficient energy to a portion of the susceptor assembly, or more specifically, to a substrate supported on the susceptor assembly. According to some embodiments, the energy provided, referred to as “annealing energy” is capable of increasing the temperature of a portion of the substrate surface up to about 1000° C., or 900° C., or 800° C., or 700° C., or 600° C., or 500° C. or 400° C. in a time frame less than about 100 nanoseconds, or less than about 50 nanoseconds, or less than about 40 nanoseconds, or less than about 30 nanoseconds, or less than about 20 nanoseconds, or less than about 10 nanoseconds. The spike in temperature from the annealing energy is sufficient to decompose a molecule adsorbed to the surface without damaging the underlying layers. The annealing energy provided by the energy source 310 provides surface heating to cause a temperature spike from about 200-350° C. to about 700-900° C. and return to about 200-350° C. in less than about 100 nanoseconds. The rate of cooling, after exposure to the annealing energy is faster than rate at which heat can transfer into the bulk substrate (i.e., the underlying layers).

The energy source is generally adapted to deliver electromagnetic energy to anneal certain desired regions of the substrate surface. Typical sources of electromagnetic energy include, but are not limited to, optical radiation sources (e.g., lasers), electron beam sources, ion beam sources, microwave energy sources, visible light sources and infra-red sources. The energy source can be continuous or pulsed. For laser anneal processes performed on a silicon containing substrate, the wavelength of the radiation is typically less than about 800 nm, and can be delivered at deep ultraviolet, infrared or other wavelengths. In one or more embodiment, the energy source may be an intense light source, such as a laser, that is adapted to deliver radiation at a wavelength between about 500 nm and about 11 micrometers.

In some embodiments, the energy source comprises a laser. Lasers can be any suitable type of laser capable of delivering high power laser radiation sufficient to rapidly heat a portion of the substrate surface to a temperature sufficient to degrade the adsorbed compounds without allowing time for the heat to transfer to and damage the bulk substrate. Suitable lasers include, but are not limited to, solid state lasers such as Nd:YAG, Nd:glass, titanium-sapphire, or other rare earth doped crystal lasers, gas lasers such as excimer lasers, for example, XeCl₂, ArF and KrF.

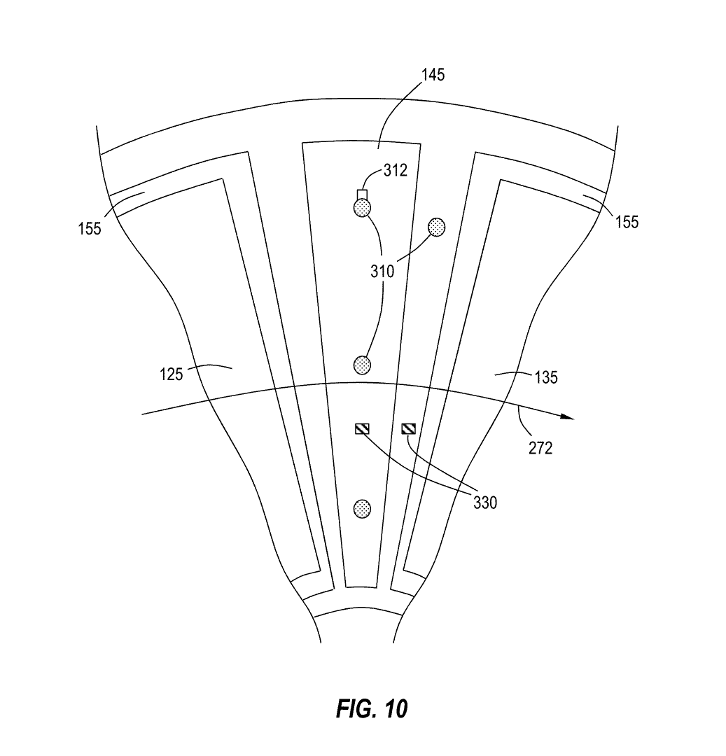

The position of the energy source 310 and any supporting components (e.g., mirrors, actuators, prisms, lenses) can be varied depending on the configuration of the gas distribution assembly. In the embodiment shown in FIGS. 8 and 9, the energy source 310 is positioned in an outer peripheral region 231 or outside the outer peripheral edge 228 of the gas distribution assembly. In other embodiments, shown in FIGS. 1 and 10, the energy source 310 is positioned within a purge gas port 145.

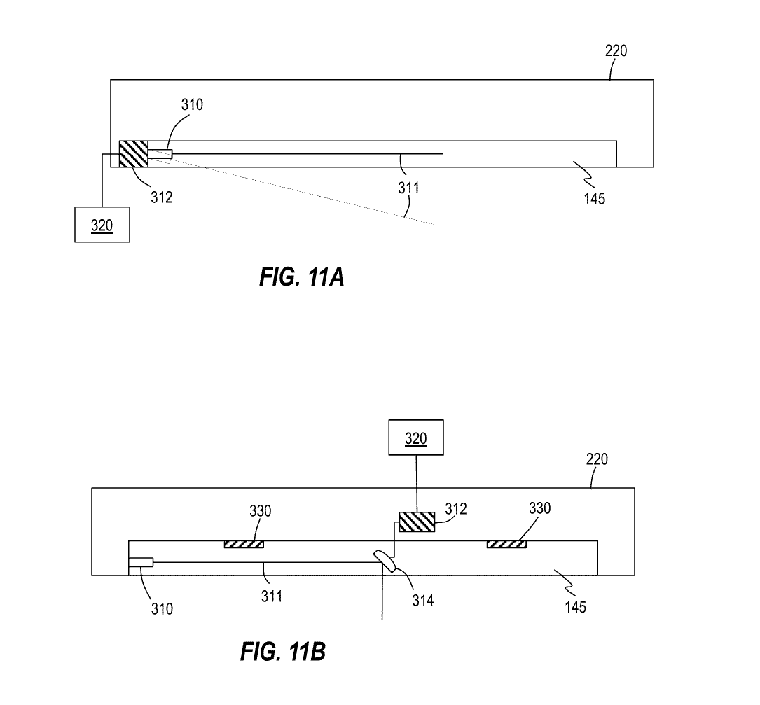

In some embodiments, at least one actuator 312 moves the energy source so that the annealing energy is moved in a direction perpendicular to the rotational axis of the susceptor assembly. The movement of the annealing energy moves between extremes at the inner diameter region and the outer diameter region, or from the inner peripheral edge to the outer peripheral edge. The distance between extremes defines the length of the movement of the annealing energy. The actuator 312 can be a motor that physically changes the orientation of the energy source 310 or can redirect the annealing energy emitted by the energy source. When referring to moving the energy source, those skilled in the art will understand, that the energy source may remain stationary with just the annealing energy being moved. For example, FIG. 11A shows a cross-section of a gas distribution plate 220 with a view into the purge gas port 145 in which an energy source 310 emits annealing energy 311. Actuator 312 moves the energy source 310 to angle the annealing energy 311 downwardly, as shown in phantom. In FIG. 11B, energy source 310 directs annealing energy 311 toward mirror 314 which redirects the annealing energy toward the susceptor. The mirror 314 is connected to actuator 312 which can change the angle of the mirror 314 to redirect the annealing energy 311 in a different direction.

Through either FIG. 11A or 11B, the actuator 312 causes the annealing energy 311 to be scanned or rastered across the surface of the susceptor assembly from the inner diameter region to the outer diameter region, or stated differently, in a direction substantially perpendicular to path 272. The movement of the annealing energy across the susceptor assembly can be smooth or rasterized. For example, the movement can be made up of a number of tiny steps occurring quickly enough to appear as a smooth movement.

Some embodiments include a controller 320 to control the actuator 312. The controller 320 can be any suitable controller capable of accurately controlling the actuator. The controller 320 can be programmed to move the annealing energy by adjusting the actuator 312 so that the annealing energy moves from the inner diameter region of the susceptor assembly to the outer diameter region in a substantially straight path. As used in this specification and the appended claims, the term “substantially straight” means that there is less than a 1% absolute deviation in the linearity over the length of the movement.

The rate of movement of the annealing energy can be adjusted depending on the specific energy source employed, the film being processed and the processing chamber. In a processing chamber with a straight path, like that of FIG. 1, the controller may move the annealing energy at a substantially uniform rate.

In a sector type system, like that of FIG. 9, the movement of the annealing energy can be uniform or graded depending on the focus of the annealing energy. When rotational movement of the susceptor assembly is taken into consideration, the outer peripheral edge of the susceptor assembly is moving faster than the inner peripheral edge. Therefore, uniform movement across the susceptor assembly would mean that there is relatively less exposure to the annealing energy per unit area near the outer diameter region than at the inner diameter region. This may not have a significant impact on the overall processing of the film as the energy source may be moving at a much faster rate than the rotation of the susceptor assembly so that the difference in residence times at the inner and outer regions is negligible or does not have an impact on the complete formation of the film with allowing heat to damage the bulk substrate.

In some embodiments, the controller moves the energy source, and therefore the annealing energy, so that the annealing energy moves slower at the outer diameter region than at the inner diameter region. The variable rate of movement can be tuned so that the residence time of the annealing energy and/or the amount of energy per unit area is substantially uniform over the range of movement.

In some embodiments, a variable focus lens 314 can be incorporated so that the size of the annealing energy at the inner diameter region is smaller than the size of the annealing energy at the outer diameter region. The size of the annealing energy refers the area occupied by the annealing energy at any given time. For example, a laser energy source projects collimated light onto the susceptor assembly. The area that the collimated light impacts is the size of the annealing energy.

Referring to FIG. 10, a portion of a gas distribution assembly according to some embodiments is shown. Here, the purge gas port 145 has three energy sources 310 positioned therein. A single controller 312 is shown, but each energy source can have a separate controller or all energy sources can be controlled by a single controller either in unison or independently. In the embodiment of FIG. 10, the three energy sources can be controlled so that the annealing energy projected from each source covers the same region of the susceptor assembly or different regions. For example, all three energy sources can be controlled so that their combined energy contacts the susceptor assembly at a single point that moves from the inner diameter region to the outer diameter region of the susceptor assembly. In another embodiment, each source moves independently so that each source directs energy to different regions of the susceptor assembly. The different regions can overlap or be separate.

The energy sources can be positioned within the purge gas port 145 as shown in the Figures, or outside the purge gas port, as shown in FIG. 10. To ensure that that there is no interaction between the process gases and the annealing energy, the energy source of some embodiments is positioned between the vacuum ports 155 positioned on either side of the purge gas port 145.

In some embodiments, at least one detector 330 is included in the system to sense or measure the temperature of one or more portions of the susceptor assembly or substrate. The detector can be any suitable type of detector including, but not limited to, pyrometers. FIG. 10 shows an embodiment with a single detector 330 positioned within the purge gas port 145 and a single detector 330 positioned outside the purge gas port. To help ensure that deposition gases do not foul the detector, in some embodiments, the detector is positioned between the vacuum ports 155 on either side of the purge gas port 145.

Some embodiments of the disclosure are directed to methods of processing a substrate. A substrate is placed into a processing chamber which has a plurality of sections, with each section separated from adjacent sections by a gas curtain. As used in this specification and the appended claims, the terms “section”, “region” and “sector” are used interchangeably to describe an area within a batch processing chamber. For example, the component shown in FIG. 9 has two sections. Upon entering the processing chamber, the substrate (also called a wafer) can be in any of the individual sections. Each section can have the same or different processing conditions from the adjacent sections. As used in this specification and the appended claims, the term “processing condition” means the entirety of the conditions within the individual section. For example, processing conditions include, but are not limited to, gas composition, pressure, flow rate, temperature and plasma. Processing conditions can be configured to, for example, deposition, etching and treatment (e.g., densification, annealing).

In the first section, the substrate, or a portion of the substrate, is exposed to a first process condition to deposit a first film on the surface of the substrate. The substrate surface can be a bare substrate surface or any layer previously deposited on the surface. For example, the surface may have a mixed composition with one part being a metal and the other a dielectric. The individual surface composition can vary and should not be taken as limiting the scope of the invention.

Any of the films deposited or formed can be a complete film, such as a metal or dielectric film, or can be a partial film as in the first half of a two-part reaction. An example of a partial film would be the chemisorption of a compound to a substrate surface that will later be decomposed by the energy source and annealing energy to produce the final film.

Formation of the first film may be, for example, the deposition of a metal hydride onto the surface of the substrate (e.g., SiH₄). After formation of the first film, the substrate is laterally moved through a gas curtain to a second section of the processing chamber. In the second section, the first film is exposed to second process conditions to form a second film. The second process condition of some embodiments comprises exposure to annealing energy from an energy source to decompose the first film. For example, silane deposited on the surface can be decomposed with a laser to form a silicon film.

During the movement from the first section to the second section, the substrate is exposed to the first process conditions, the second process conditions and a gas curtain which separates the two. The gas curtain can be, for example, a combination of inert gases and vacuum to ensure that there is minimal, if any, gas phase reaction between the first process conditions and the second process conditions. At some time during the movement, part of the surface is exposed to the first process conditions, another part of the surface is exposed to the second process conditions and an intermediate portion, between the other two portions, of the substrate is exposed to the gas curtain.

In some embodiments, the gas curtain includes the energy source which exposes the portion of the substrate within the gas curtain to the annealing energy. In an embodiment of this sort, the second process condition can be the same as the first process condition so that a thicker film can be deposited and annealed as the substrate rotates through the processing chamber.

The exposure to the first process conditions and the second process conditions can be repeated sequentially to grow a film of desired thickness. For example, the batch processing chamber may contain two sections with the first process conditions and two sections of the second process conditions in alternating pattern, so that rotation of the substrate around the central axis of the processing chamber causes the surface to be sequentially and repeatedly exposed to the first and second process conditions so that each exposure causes the film thickness (for depositions) to grow.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein plasmas may not be required. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the desired separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present invention are the Centura® and the Endura®, both available from Applied Materials, Inc., of Santa Clara, Calif. The details of one such staged-vacuum substrate processing apparatus is disclosed in U.S. Pat. No. 5,186,718, entitled “Staged-Vacuum Wafer Processing Apparatus and Method,” Tepman et al., issued on Feb. 16, 1993. However, the exact arrangement and combination of chambers may be altered for purposes of performing specific parts of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposure to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present invention, other and further embodiments of the disclosure may be devised without departing from the basic scope thereof, and the scope thereof is determined by the claims that follow.

What is claimed is:

1. A processing chamber comprising:
a generally circular gas distribution assembly comprising a plurality of elongate gas ports in a front face of the gas distribution assembly, the plurality of elongate gas ports extending from an inner diameter region to an outer diameter region of the gas distribution assembly, the plurality of gas ports comprising at least one first reactive gas port to deliver a first reactive gas to the processing chamber, a purge gas port to deliver a purge gas to the processing chamber and a vacuum port to evacuate gases from the processing chamber, the vacuum port positioned between the first reactive gas port and the purge gas port;
a generally circular susceptor assembly to rotate at least one substrate in a substantially circular path about a rotational axis, the susceptor assembly positioned below the gas distribution assembly so that a top surface of the susceptor assembly is substantially parallel to the front face of the gas distribution assembly, the susceptor assembly having an inner diameter region and an outer diameter region; and
at least one energy source oriented to direct annealing energy toward the top surface of the susceptor assembly.

2. The processing chamber of claim 1, wherein the energy source is positioned within the purge gas port.

3. The processing chamber of claim 1, further comprising at least one actuator to move the energy source so that the annealing energy is moved in a direction perpendicular to the rotational axis of the susceptor assembly.

4. The processing chamber of claim 3, further comprising a controller to control the actuator.

5. The processing chamber of claim 4, wherein the controller reciprocally moves the annealing energy from the inner diameter region to the outer diameter region of the susceptor assembly in a substantially straight path.

6. The processing chamber of claim 5, wherein the controller moves the annealing energy at a substantially uniform rate.

7. The processing chamber of claim 6, further comprising a variable focus lens to focus the annealing energy on the susceptor assembly so that the annealing energy has a size at the inner diameter region that is smaller than the size at the outer diameter region.

8. The processing chamber of claim 5, wherein the controller moves the energy source so that the annealing energy moves slower at the outer diameter region than the inner diameter region.

9. The processing chamber of claim 8, wherein during rotation of the susceptor assembly, the annealing energy has a substantially uniform residence time from the inner diameter region to the outer diameter region.

10. The processing chamber of claim 1, wherein the energy source comprises a laser.

11. The processing chamber of claim 1, wherein there is a plurality of energy sources positioned within the purge gas port.

12. The processing chamber of claim 1, further comprising at least one detector to sense temperature of one or more portions of the substrate.

13. The processing chamber of claim 12, wherein the detector is positioned within the purge gas port.

14. The processing chamber of claim 1, further comprising a second vacuum port positioned on an opposite side of the purge gas port from the vacuum port and the energy source is positioned in a region after the second vacuum port.

15. A processing chamber comprising:
a generally circular gas distribution assembly comprising a plurality of elongate gas ports in a front face of the gas distribution assembly, the plurality of elongate gas ports extending from an inner diameter region to an outer diameter region of the gas distribution assembly, the plurality of gas ports comprising, in order, a first reactive gas port to deliver a first reactive gas to the processing chamber, a first vacuum port to evacuate gases from the processing chamber, a purge gas port to deliver a purge gas to the processing chamber and a second vacuum port to evacuate gases from the processing chamber;
a generally circular susceptor assembly to rotate at least one substrate in a substantially circular path about a rotational axis, the susceptor assembly positioned below the gas distribution assembly so that a top surface of the susceptor assembly is substantially parallel to the front face of the gas distribution assembly, the susceptor assembly having an inner diameter region and an outer diameter region; and
at least one energy source positioned between the first vacuum port and the second vacuum port and oriented to direct annealing energy toward the top surface of the susceptor assembly, the annealing energy movable in a direction from the inner diameter region to the outer diameter region of the susceptor assembly.

16. A processing method comprising:
positioning a substrate on a rotatable susceptor assembly in a processing chamber;
laterally moving the substrate around a central axis to move the substrate beneath a first reactive gas port of a gas distribution assembly, the first reactive gas port providing a first reactive gas to the processing chamber;
exposing the substrate to a first process condition comprising the first reactive gas to form a partial film on the substrate surface;
laterally moving the substrate around the central axis through at least one vacuum region defining a boundary of the first process condition, the gas distribution assembly having in the vacuum region a vacuum port to evacuate gases from the processing chamber; and
exposing the substrate surface to annealing energy to convert the partial film to a film.

17. The processing method of claim 16, wherein the substrate is moved from the first process condition through the vacuum region, a purge gas region and second vacuum region into a second process condition.

18. The processing method of claim 17, wherein the substrate is exposed to the annealing energy in the purge gas region.

19. The processing method of claim 17, wherein the substrate is exposed to the annealing energy in the second process condition.

20. The processing method of claim 17, wherein the vacuum region, purge gas region and second vacuum region have a width less than the diameter of the substrate so that during lateral movement the substrate can be exposed to at least two of the first process condition, vacuum region, purge gas region or the second vacuum region.
